(19) United States
(12) Patent Application Publication
(10) Pub. No.: US 2003/0193420 A1
(43) Pub. Date: Oct. 16, 2003

(54) Keyboard control apparatus

(75) Inventor: Heng Wang, Hsinchu (TW)

Correspondence Address: TROXELL LAW OFFICE PLLC, SUITE 1404, 5205 LEESBURG PIKE, FALLS CHURCH, VA, 22041, US

(73) Assignee: ENE Technology Inc.

(21) Appl. No.: 10/409,132

(22) Filed: Apr. 9, 2003

(30) Foreign Application Priority Data
Apr. 10, 2002 (TW) 091204684

(51) Int. Cl. H03M 11/00

(52) U.S. Cl. 341/26

(57) ABSTRACT

A control apparatus for a built-in keyboard in notebook computers includes an keyboard encoder which has a serial/parallel port interface to transmit a keyboard scan code to a keyboard controller and to receive commands from the keyboard controller. The keyboard controller is integrated in a core-logic chip set. The keyboard encoder also includes a series bus interface to download matrix value pre-stored in the core-logic chip set to the keyboard encoder.

### BACKGROUND OF THE INVENTION

1. Field of the Invention

The invention relates to a keyboard controller built in a core-logic chip set located in the built-in keyboard of a notebook computer to connect a keyboard encoder through a general simple connection interface and transmit keyboard matrix value to the keyboard encoder.

2. Description of the Prior Art

Conventional notebook computers have a keyboard encoder in the built-in keyboard that is designed and included in a micro-controller. The micro-controller also includes control functions of a keyboard controller. The matrix value of the keyboard encoder is downloaded to the internal storage of the micro-controller through a host interface, or pre-stored in the firmware of the micro-controller.

Refer to FIG. 1 for the structure of a keyboard controller in a conventional notebook computer. There is a micro-controller 20 connecting to a core-logic chip set 10 of the notebook computer. In the micro-controller 20, there is a keyboard controller 22 to transmit/receive output/input signals from the core-logic chip set 10 through a host interface 12. The micro-controller 20 also has a keyboard encoder 24 connecting to the keyboard controller 22 to match scan input and output value with a matrix table stored in the memory 26 to generate a scan code. The memory 26 also connects to the keyboard controller 22 to receive output from the keyboard controller 22 corresponding to the value in the memory.

In recent years there are growing demands and technologies to integrate additional features, capacity and functions in a single chip circuitry. In order to integrate multiple functions in a single chip and to reduce cost, many vendors try to combine the keyboard controller in the core-logic chip set. However, to integrate the keyboard encoder in the core-logic chip set is still difficult because many legs are involved.

The main problem is that the keyboard encoder cannot download keyboard matrix value from the micro-controller 20 through the host interface. To use the micro-controller 20 to execute the control functions of the keyboard controller 22 and keyboard encoder 24 makes circuit design more complicated and cost higher. In addition, using the host interface 12 to transfer data of the core-logic chip set 10 also makes circuit design more complicated.

### SUMMARY OF THE INVENTION

The object of the invention is to provide a simple and low cost transmission interface to download keyboard matrix value to a single and independent programmable keyboard encoder. The invention manly includes a serial/parallel port interface (may be a PS/2 interface) in a keyboard encoder to transfer keyboard scan code to a keyboard controller, and to receive commands issued from the keyboard controller. In addition, the keyboard encoder includes a series bus interface to download keyboard matrix value. During system operations, the scan controller of the keyboard encoder is disabled, and system BIOS downloads the matrix value to the keyboard encoder. After the download is completed, the keyboard encoder is enabled to perform scan and transmit the scan code to the keyboard controller.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a block diagram of the circuit of a built-in keyboard of a conventional notebook computer.

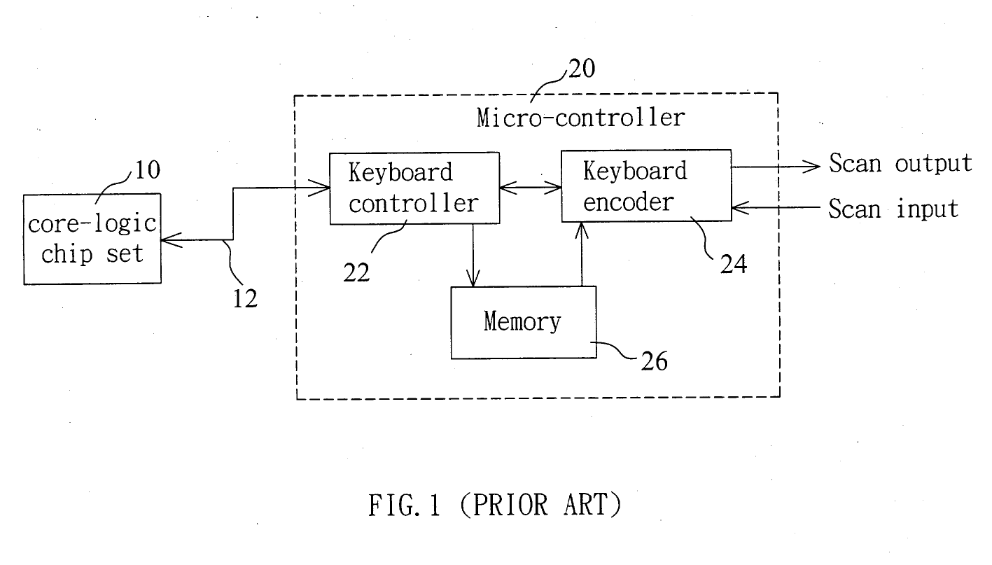

FIG. 2 is a block diagram of circuit of a built-in keyboard for a notebook computer according to the invention.

### DESCRIPTION OF THE PREFERRED EMBODIMENT

A general typical notebook computer includes a built-in keyboard which has a built-in matrix for the keyboard layout. Data stored on the matrix are scanned by a keyboard encoder and the position of the depression also is defined to generate a code corresponding to the keyboard that has been scanned. The code is related to the pre-stored matrix value. The invention provides a novel keyboard control apparatus to download the matrix value to a programmable keyboard encoder through a series interface, and also to effectively simplify keyboard encoder design to prevent the high cost of using the micro-controller.

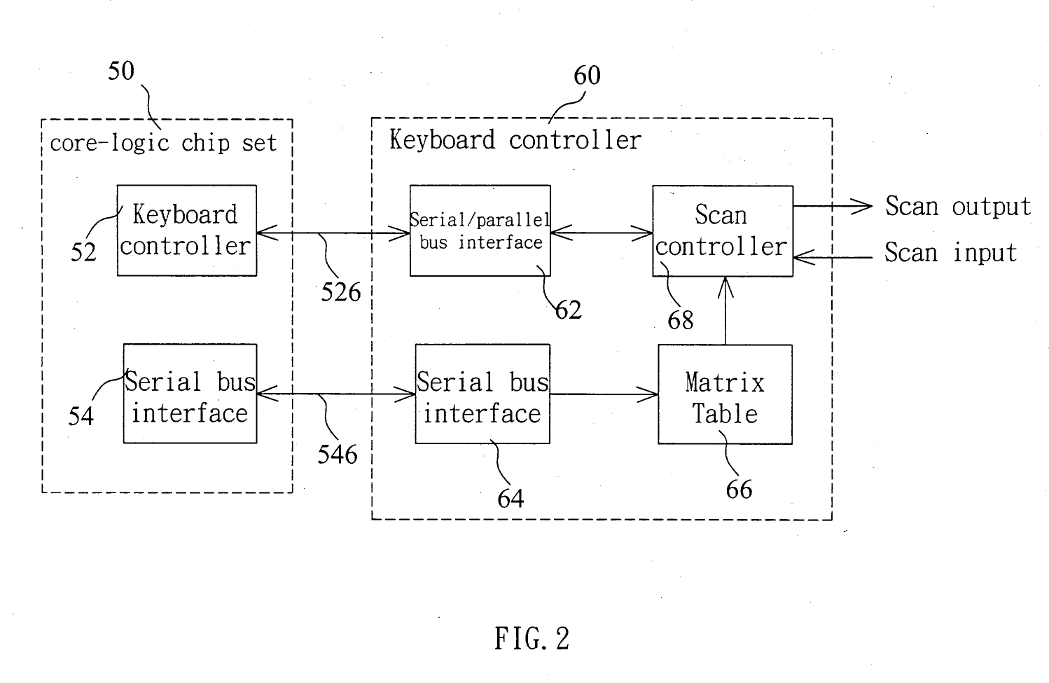

Refer to FIG. 2 for the block diagram of the circuit of a built-in keyboard for a notebook computer according to the invention. The notebook computer according to the invention includes a core-logic chip set 50 which has a keyboard controller 52 and a serial bus interface 54. The core-logic chip set 50 connects to a keyboard encoder 60 which is radically different from conventional designs. In practice, the keyboard encoder 60 is a programmable encoder which may be programmed according to user's requirements. The keyboard encoder 60 includes a serial/parallel bus interface 62 which may be a general PS/2 connection interface adopted in general computers. The serial/parallel bus interface 62 connects to the keyboard controller 52 of the core-logic chip set 50 to link signals of the keyboard encoder 60 and the keyboard controller 52. It may be accomplished by simply connecting a PS/2 bus.

The keyboard encoder 60 also includes a scan controller 68 which connects to the serial/parallel bus interface 62 to perform control of keyboard scan operations. It has an input end to input scan input signals and an output end to deliver scan output signals. The keyboard encoder 60 further includes a serial bus interface 64 connecting to the serial bus interface 54 of the core-logic chip set 50 for downloading a set of table value into the keyboard encoder 60. It may adopt a general serial bus connection such as a COM1 Port connection line used in the general computers to achieve the download transmission operation. The keyboard encoder 60 also has a matrix table 66 which contains table value. It has an input end connecting to the serial bus interface 64 and an output end connecting to the scan controller 68. The contained value in the matrix table 66 is stored in the memory, and may be stored in a pre-stored fashion. Moreover, download of the contained value of the matrix table 66 is transmitted from the core-logic chip set 50 to the keyboard encoder 60 through the serial bus.

When the notebook computer is in operation, the scan controller 68 of the keyboard encoder 60 is disabled initially, and the BIOS downloads the matrix value to the keyboard encoder 60. When the download is completed, the keyboard encoder 60 is enabled to scan and transmit the scan code to the keyboard controller 52.

By means of the construction and embodiment set forth above, the invention can simply transmit keyboard matrix value and control signals through the connection of computer transmission interfaces and greatly reduce the cost. In addition, the keyboard controller 52 may be built in the core-logic chip set 50 to simplify the design of the keyboard encoder 60 to prevent the high cost of using micro-controller to perform keyboard controller and keyboard encoder.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

I claim:

1. A keyboard control apparatus comprising a core-logic chip set which includes a keyboard controller and a serial bus interface for connecting to a keyboard encoder, wherein the keyboard encoder includes:
a serial/parallel bus interface connecting to the keyboard controller of the core-logic chip set for linking signals of the keyboard encoder and the keyboard controller;
a scan controller connecting to the serial/parallel bus interface to perform control of keyboard scan operations;
a serial bus interface connecting to the serial bus interface of the core-logic chip set to download a set of table value to the keyboard encoder; and
a matrix table contained the table value having an input end connecting to the serial bus interface and an output end connecting to the scan controller.

2. The keyboard control apparatus of claim 1, wherein the connecting between the keyboard controller and the serial/parallel bus interface is a PS/2 interface.

3. The keyboard control apparatus of claim 1, wherein the connecting between the serial bus interface of the core-logic chip set and the serial bus interface of the keyboard encoder is a serial bus.

4. The keyboard control apparatus of claim 1, wherein input of the scan controller includes a scan input signal.

5. The keyboard control apparatus of claim 1, wherein output of the scan controller includes a scan output signal.

6. The keyboard control apparatus of claim 1, wherein the contained value of the matrix table is stored in a memory.

7. The keyboard control apparatus of claim 1, wherein the contained value of the matrix table is pre-stored in the core-logic chip set.

8. The keyboard control apparatus of claim 1, wherein the contained value of the matrix table is downloaded from the core-logic chip set to the keyboard encoder through the serial bus.

9. The keyboard control apparatus of claim 1, wherein keyboard encoder is a programmable encoder.
